(19) United States
(12) Patent Application Publication
(10) Pub. No.: US 2019/0086459 A1
(43) Pub. Date: Mar. 21, 2019

(54) SYSTEMS AND METHODS FOR MEASURING AND CHARACTERIZING ANTENNA PERFORMANCE

(71) Applicant: The Governors of the University of Alberta, Edmonton (CA)

(72) Inventors: Rezvan Rafiee Alavi, Edmonton (CA); Ali Kiaee, Edmonton (CA); Rashid Mirzavand, Edmonton (CA); Pedram Mousavi, Edmonton (CA); Ruska Patton, Edmonton (CA)

(21) Appl. No.: 16/030,626

(22) Filed: Jul. 9, 2018

Related U.S. Application Data
(60) Provisional application No. 62/529,731, filed on Jul. 7, 2017.

(51) Int. Cl. G01R 29/10

(52) U.S. Cl. CPC G01R 29/10

(57) ABSTRACT

A ground filtering source reconstruction method and system, for a near field measurement system comprising a scanner board with an array of integrated probes that are backed by a ground plane and at least one coupled RF receiver that captures near-field data from an antenna-under-test (AUT) or device-under-test (DUT).

### FIELD OF THE INVENTION

The present invention relates to systems and methods for measuring and characterizing antenna performance.

### BACKGROUND

Near-field measurement systems are widely used for the characterization of large and/or low frequency antennas for which far-field or compact range measurement systems become too costly and in some cases impractical to use. The compact size of these near-field measurement systems allows for integration of measurement probes in planar, circular, and other array configurations. If the measurements are done by an array of sensors, mechanical movement of the antenna-under-test (AUT) or device-under-test (DUT) may be reduced or eliminated, and hence the measurement time may be reduced. In the case of planar near-field measurements, the simplicity of the near-field to far-field transformation algorithms along with the array based approach results in almost real-time far-field characterization of the AUT in a hemisphere. A further reduction in measurement system size can be achieved if measurements can be done in the reactive region of the near-field, which is traditionally avoided because of the potential for reflection and coupling with the antenna.

Measurement in this reactive region is sometimes called very near-field measurement. An example of such a planar very-near-field antenna measurement system is the RFxpert® (EMSCAN Corporation, Canada) commercial product, which comprises an array of 1600 rapidly switchable probes printed on a 45 cm×45 cm printed circuit board (PCB). The orthogonal H-field components (magnitude and phase) measured by the probes are transformed to a far-field pattern in a hemisphere using a plane-wave-spectrum (PWS) expansion.

As these systems usually use a finite-ground plane, separating the RF and digital circuits for electromagnetic compatibility and electromagnetic interference (EMC/EMI) reasons, any possible effects that the ground plane might introduce to the entire measurement process should be accounted for. If the DUT is a microwave or high-speed digital circuit, the current and field perturbation due to the ground plane can be tolerated to some extent. However, if the DUT is an antenna, the ground plane induced protuberance will be significant and should preferably be accounted for while doing near-field to far-field transformation.

Well-known methods for near-field to far-field transformation and even field reconstruction are based on the modal expansion method, such as the PWS method. In conventional modal expansion methods, the fields radiated by the AUT are expanded in terms of planar, cylindrical, or spherical wave functions. Measured near fields are used to find out the coefficients of this expansion. These modes are used to extract far-field data of the radiator [2]-[5]. In the case of sinusoidal orthogonal modes, the expansion coefficients can be obtained by applying classic Fourier transform to the measured fields. Despite the inability to model evanescent fields, these methods have the advantage of speed. Modal expansion based methods can even benefit from hardware accelerated FFT calculators. This fact makes modal expansions a good choice for EMC/EMI diagnosis, where having a real-time response is preferred.

However, it is known that transformation accuracy degrades if there are evanescent fields of significant energy present on the measurement plane. This contradicts the basic underlying assumption of measurement fields consisting of propagating modes. Also, since the fields outside the measurement region are assumed to be zero, far-field solid angle accuracy range degrades due to truncation effect on the edges [4]. Far fields are just determined precisely over a particular angle which is dependent on the measurement configuration. Furthermore, these truncation results introduce spurious side lobes in the far-field.

The effect of these side-lobes can be at least partly alleviated by using spatial low-pass filters [4] which gradually force the fields to vanish towards the measurement plane edges. However, the filters themselves can potentially introduce new distortions.

To alleviate the effects introduced by the ground plane, especially those affecting far-field, a source reconstruction method (SRM) may be implemented. In a conventional SRM approach, the measured electromagnetic fields are back-projected to a fictitious surface that reconstructs the measured fields [7, 8, 13].

A planar array of infinitesimal magnetic dipoles may be used as a fictitious layer which is assumed to be laid on infinite perfectly electric conductor (PEC) plane [6, 7]. Then, antenna far-fields are calculated through array far-field rules based on the complex dipoles amplitudes. Source reconstruction of fields can be accomplished using an equivalent closed surface, embracing all the volume [8], which is different from the space [9]. In comparison with the modal expansion methods, especially those dealing with open measurement surfaces, there are no far-field distortions, since it does not suffer from the truncation effect. However, the process time is greater than that of the modal expansion based techniques. Attempts have been made to enhance the accuracy of the reconstructed currents and far-field patterns afterward, where AUT is modeled by a closed arbitrary fictitious surface which contains all materials that differ from free space. Both electric and magnetic currents exist on this surface. Love's equivalence principle is then used to enforce tangential E/H fields to vanish on an inner surface which is inside the fictitious one [9]. Essentially classical jump conditions were used to simplify the equations and avoid having integral equations of the second kind. Other works are more inclined towards PCB applications for EMC/EMI purposes. Others have used a Genetics Algorithm (GA) optimization method to back project measured near-fields to currents on PCB tracks [10]. Still others have tried to find equivalent sources composed of electric and/or magnetic dipoles through least square method or other iterative minimization techniques [10]-[12].

There is a need in the art for methods and systems for calibrating or correcting measurements made by a reactive near-field scanner, to account for the

### SUMMARY OF THE INVENTION

The present invention relates to a scanner system of calibrating and/or correcting a measurement made using a reactive near-field scanner of an antenna-under-test (AUT). The scanner may comprise an array of integrated probes that are each individually associated with an RF receiver or are multiplexed to single RF receiver, to capture near-field data in proximity of an AUT. The scanner system generates equivalent electromagnetic sources that match the near-field data from the AUT. These equivalent sources may then be transformed into far-field data or used to highlight features of the AUT in detail.

The present invention may comprise a reconstruction method to address the type of measurement in which there exists a ground plane beneath a probe array. In one embodiment, the method comprises one of four different types of reconstruction methods. One scenario, in which there exist only electric currents, may be a preferred method, based on simulation and measurement results. The examples described herein show that the far-field accuracy, defined by an angular threshold in degrees, may increase from 7 to 40 and 8 to 54 in one case, and 27 to 83 and 17 to 43 in the other one. In another embodiment, for diagnosis purposes, a JMB method which provides both J and M information, may be a preferred option.

### BRIEF DESCRIPTION OF THE DRAWINGS

In the drawings shown in the specification, like elements may be assigned like reference numerals. The drawings are not necessarily to scale, with the emphasis instead placed upon the principles of the present invention. Additionally, each of the embodiments depicted are but one of a number of possible arrangements utilizing the fundamental concepts of the present invention.

FIG. 1. A typical near-field measurement scenario in presence of ground.

FIG. 2. Depiction of a source reconstruction problem in which H-field probes are immediately next to a rectangular metallic ground plane.

FIG. 3A. The depiction of the equivalent problem for source reconstruction closed fictitious surface.

FIG. 3B. The depiction of the equivalent problem for source reconstruction open fictitious surface.

FIG. 4A. Current density′ complex magnitude was calculated using commercial solver with 13 iterations.

FIG. 4B. Current density′ complex magnitude was calculated using in-house code with 13 iterations and 0.5 cm size mesh.

FIG. 4C. Current density′ complex magnitude was calculated using commercial solver with 10 iterations.

FIG. 4D. Current density′ complex magnitude was calculated using in-house code with 10 iterations and 1 cm size mesh.

FIG. 5A. Normalized Far-field magnitude E_{θ}.

FIG. 5B. Normalized Far-field magnitude E_{ϕ}.

FIG. 6A. Schematic of the slot antenna and the fictitious surfaces (elliptic cross-section).

FIG. 6B. Schematic of the slot antenna and the fictitious surfaces (circular cross-section).

FIG. 7A. Comparison between different solvers for E_{ϕ} in the Slot antenna Monopole at 1.5 GHz.

FIG. 7B Comparison between different solvers for E_{θ} in the Slot antenna Monopole at 1.5 GHz.

FIG. 8A. Depiction of a monopole antenna (elliptic cross-section).

FIG. 8B. Depiction of a monopole antenna (circular cross-section).

FIG. 8C shows a comparison between different solvers for E_{ϕ} in the monopole antenna.

FIG. 8D shows a comparison between different solvers for E_{θ} in the monopole antenna.

FIG. 9. Reconstructed E and H currents on the fictitious layer. Color-map on the right-hand side is for H fields and the one on the left is for E Fields.

FIG. 10. L-curve for regularization.

### DETAILED DESCRIPTION OF PREFERRED EMBODIMENTS

In embodiments of the present invention, the effect of ground plane is accounted for by back-projecting the measured near-fields back to at least two surfaces simultaneously, which are (1) the open/closed surface representing radiating elements and (2) a rectangular plane representing a ground plane. It is important to note that the number of surfaces can be increased depending upon the physical structure of the radiator or scanner. In doing so, there are a number of Method of Moments (MOM) related challenges to be addressed.

The material between the radiator and the scan surface may be simply modelled as a vacuum or by a non-vacuum medium with arbitrary dielectric properties like electric and magnetic conductivity or loss; anisotropy; or inhomogeneity. Information about the dielectric properties of the media is assumed to be known.

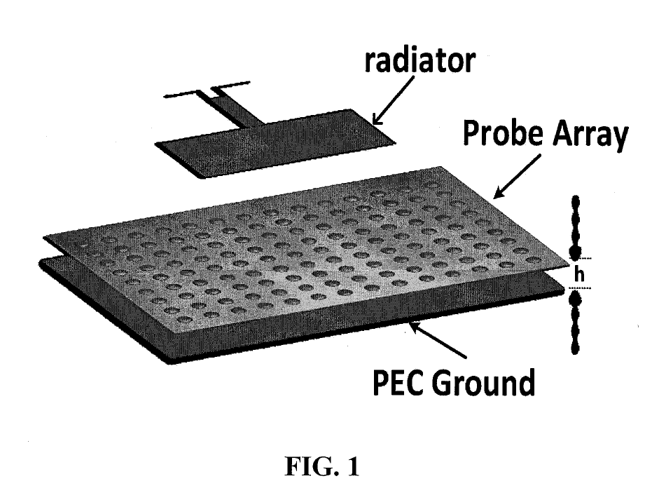

As described above, the ground plane induced protuberance may be significant and should preferably be accounted for while doing near-field to far-field transformation. The problem can be visualized as shown in FIG. 1, where a radiator (AUT) is placed on top of a planar array of H-field probes. The H-field probe array is placed on top of a finite perfect electrical conductor (PEC) ground plane. In a typical measurement scenario, a single tone frequency synthesizer powers the AUT, which illuminates the probe array, and the received power on the probe array may be detected. Once complex voltages are read out of the probes, they are assumed to represent the magnetic field intensity at the center of probes

The size and position of the radiator are presumed to be the only information given. As such, information about shape or materials of the radiator is not known. Retrospectively, various kinds of structures have been used to model the radiators including electric [8] or magnetic [7] current sheets and closed surfaces of both electric and magnetic currents [9]. In the case of closed surfaces, it is possible to apply the boundary conditions of type zero tangential E/H [9] to increase the accuracy. Each of these approaches are described herein, and a preferred method may be selected based on the far-field and near-field accuracies.

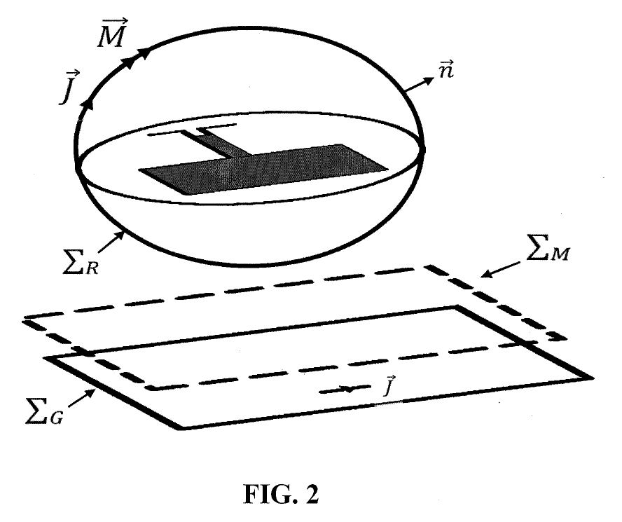

FIG. 2. depicts a reference ground de-embedded source reconstruction problem. The input information for the problem are the complex values of the tangential magnetic field on the planar measurement surface denoted by Σ_{M}.

### I. Integral Equation

The integral equations can be constructed by relating the sources, measured fields and any existing boundary conditions to the original problem [14]. For the equivalent problem described previously, integral equations that link the source currents and electric/magnetic fields in free space, can be written as follows, with assuming e^{jωt} time dependence [14]

$$\begin{matrix}L & \\ E ( r ) = - {η}_{0} Λ ( J ; r ) + K ( M ; r ) & ( 1. a ) \\ H ( r ) = - \frac{1}{{η}_{0}} Λ ( M ; r ) - K ( J ; r ) where & ( 1. b ) \\ Λ ( J ; r ) = {jk}_{0} {\int }_{{Σ}_{R} + {Σ}_{G}} [ J ( {r}^{′} ) + \frac{1}{{k}_{0}^{2}} ∇ {∇}_{s}^{′} \cdot J ( {r}^{′} ) ] g ( r , {r}^{′} ) {ds}^{′} & ( 2. a ) \\ K ( M ; r ) = {\int }_{{Σ}_{R} + {Σ}_{G}}^{ } M ( {r}^{′} ) \times ▽g ( r , {r}^{′} ) {ds}^{′} & ( 2. b ) \\ g ( r , {r}^{′} ) = \frac{{e}^{- {jk}_{0} \vert r - {r}^{′} \vert}}{4 π \vert r - {r}^{′} \vert} where & ( 2. c ) \\ {η}_{0} = \sqrt{\frac{{μ}_{0}}{{ϵ}_{0}} ,} {k}_{0} = \sqrt{{μ}_{0} \times {ϵ}_{0}} & \end{matrix}$$

and ∇ₛ′ is the surface divergence factor.

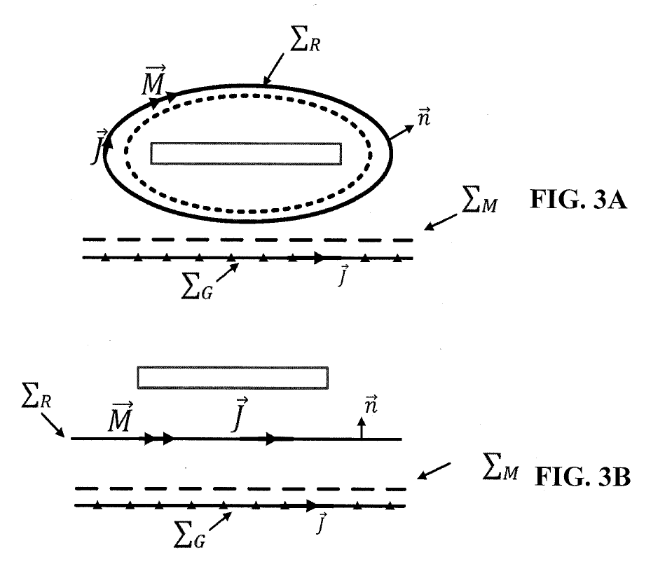

So far, fields in free space have been related to an arbitrary distribution of sources, without forcing any relation between sources present in the space nor applying any boundary condition due to the ground presence. FIGS. 3A and 3B shows two typical setups based on defined integral equations. The first and second setups represent scenarios with closed and open fictitious layers, respectively.

### A. Pure Electric Currents

In this scenario, a fictitious layer only contains electric currents (J) and therefore it is applicable to both setups depicted in FIGS. 3A and 3B. The system of equations for this setup can be summarized as:

n×[−K(Jₛ;r_{Σ}_{_{M}})−K(J_{G};r_{Σ}_{_{M}})]=H_{M}(r_{Σ}_{_{M}}) (3-a)

n×[−η₀(Λ(Jₛ;r_{Σ}_{_{G}})−η₀Λ(J_{G};r_{Σ}_{_{G}})]=0 (3-b)

where H_{M}(r_{Σ}_{_{M}}) represents the measured tangential magnetic field.

B. Electric and Magnetic Currents with No Inner Boundary Conditions

In this scenario, both electric and magnetic currents (J_{S}, M_{S}) are considered on the fictitious surface. Since Love's equivalence boundary condition is not being enforced, it might reduce the back projection accuracy. But the setup becomes applicable to both opened and closed (FIGS. 3A and 3B) setups. The system of equations for this setup can be written as

$$\begin{matrix}n \times ( - \frac{1}{{η}_{0}} Λ ( {M}_{s} ; {r}_{{Σ}_{M}} ) - K ( {J}_{s} ; {r}_{{Σ}_{M}} ) - K ( {J}_{G} ; {r}_{{Σ}_{M}} ) ) = n \times {H}_{M} ( {r}_{{Σ}_{M}} ) & \text{(4-a)} \\ n \times [ - {η}_{0} ( L ( {J}_{s} ; {r}_{{Σ}_{G}} ) - {η}_{0} L ( {J}_{G} ; {r}_{{Σ}_{G}} ) + K ( {M}_{s} ; {r}_{{Σ}_{G}} ) ] = 0 & \text{(4-b)}\end{matrix}$$

C. Electric and Magnetic Currents with LOVE's Equivalence Boundary Condition

In this scenario, there are both electric and magnetic currents present on the fictitious layer. Also, a boundary condition of zero E/H is applied to force Love's equivalence theorem [9]. In the next step, the electric and magnetic currents on the fictitious layer are implicitly related to each other.

Using electromagnetic quantities [9][15][16], the interested boundary condition can be derived as [9]:

$$- {η}_{0} Λ ( {J}_{s} ; {r}_{{Σ}_{R}} ) + K ( {M}_{s} ; {r}_{{Σ}_{R}} ) - {η}_{0} Λ ( {J}_{G} ; {r}_{{Σ}_{R}} ) = - \frac{1}{2} M ( {r}_{{Σ}_{R}} ) \qquad ( 5 )$$

The classical jump condition can be used to escape having to deal with an integral equation of the second kind which is associated with poor accuracy and well conditioning [9][16]. Hence, the integral equation in (5) can be rewritten by a limit of a first kind integral equation and the system of equations become as follows.

$$\begin{matrix}n \times ( - \frac{1}{{η}_{0}} Λ ( {M}_{s} ; {r}_{{Σ}_{M}} ) - K ( {J}_{s} ; {r}_{{Σ}_{M}} ) - K ( {J}_{G} ; {r}_{{Σ}_{M}} ) ) = n \times {H}_{M} ( {r}_{{Σ}_{M}} ) & \text{(6-a)} \\ {lim}_{r \to {Σ}_{R}^{-}} n \times ( - {η}_{0} Λ ( {J}_{s} ; r ) + K ( {M}_{s} : r ) - {η}_{0} Λ ( {J}_{G} ; r ) ) = 0 & \text{(6-b)} \\ n \times [ - {η}_{0} ( Λ ( {J}_{s} ; {r}_{{Σ}_{G}} ) - {η}_{0} Λ ( {J}_{G} ; {r}_{{Σ}_{G}} ) + K ( {M}_{s} ; {r}_{{Σ}_{G}} ) ] = 0 & \text{(6-c)}\end{matrix}$$

It means tangential electric field should go to zero as moving toward inside the space enclosed by fictitious layer. Imposing this condition is equivalent to holding field equivalence problem [9] [17], i.e. M=−n×E, J=n×H.
D. Pure Electric Currents with PMC Boundary Condition

In this scenario, the fictitious layer only contains electric currents. Therefore, only the magnetic fields on the fictitious layer are forced to be zero. Here, since there are no magnetic currents on the fictitious layer, the right-hand side of (5) goes to zero.

As a direct consequence, it does not end up in an integral equation of the second kind; so using the jump condition is not necessary. The system of equations for this scenario can be written as follows:

n×(K(Jₛ;r_{Σ}_{_{M}})−K(J_{G};r_{Σ}_{_{M}}))=n×H_{M}(r_{Σ}_{_{M}}) (7-a)

n×(K(Jₛ;r_{Σ}_{_{R}})−K(J_{G};r_{Σ}_{_{R}}))=0 (7-b)

n×[−η₀(Λ(Jₛ;r_{Σ}_{_{G}})−η₀Λ(J_{G};r_{Σ}_{_{G}})+K(Mₛ;r_{Σ}_{_{G}})]=0 (7-c)

### II. MOM Discretization

The total setup is illustrated and exemplary integral equations of the problem are defined, so far. In this section, one embodiment of a discretization process is presented. All regions shown in FIGS. 3A and 3B, excluding the measurement surface (Σ_{M}), should be discretized. The triangular mesh scheme may be used, although any basis function applicable to integral equations can be used to model the electric and magnetic surface currents. RWG basis functions [18] may be used to expand the vector source currents on the source surfaces for both electric and magnetic currents. RWG basis function's normal component is continuous on the shared edge which they are defined on. Hence, the line charges on the edges of the triangles can be neglected [14][18]. They also represent a complete basis for expanding of both currents and charges [19], as follows, and are useful to model electromagnetic structures, even those with shapes edges like cubes [18].

$${J}_{{Σ}_{x}} ( {r}^{′} ) = {\sum }_{tri ( i ) ∈ {Σ}_{x}}^{ } {C}_{i} {f}_{i} ( {r}^{′} ) , {M}_{{Σ}_{x}} ( {r}^{′} ) = {η}_{0} {\sum }_{tri ( i ) ∈ {Σ}_{x}}^{ } {C}_{i} {f}_{i} ( {r}^{′} ) \qquad ( 8 )$$

where η₀ is used as a factor for normalization purposes without which an unbalanced interaction matrix would result. It would both affect the accuracy and well-posedness of the final matrix.

The number of unknown coefficients for sources differs depending on the type of scenario used. In one embodiment, the most general one which contains both electric and magnetic currents available on the fictitious surface, besides a boundary condition, is selected. Thus, it is like a general scenario, effectively, and the approach can easily get generalized to account for integral equations in others, as well. The first equation in the system of equations (6-a) forces all sources in the system to radiate the same fields as the measured magnetic fields do on the measurement surface. The MOM discretization for this part is relatively straightforward due to that there is no need for test functions. However, for the two remaining equations test functions may be used to increase the accuracy. By equation 6-c, tangential electric fields are forced to be zero on the ground plane. For better enforcing the boundary condition, the fields are investigated on both sides of equation, using RWG test functions, although other test functions may be used, as it is done in a conventional scattering problem [14]. However, here we have both point-matched and RWG tested fields for measured and boundary conditions respectively. As such, in this case, two discretization techniques for the operators are required. Using the RWG basis functions, one can utilize the feature of continuity of normal component on the sharing edge and define the A operators for testing and point-matching as [14][20]:

$$\begin{matrix}{Λ}_{m , n}^{1} := ik {\int }_{{s}_{m}}^{ } {{drf}_{m} ( r )}_{\cdot } {\int }_{{s}_{n}}^{ } {dr}^{′} g ( r , {r}^{′} ) {f}_{n} ( {r}^{′} ) - \frac{i}{k} {\int }_{{s}_{m}}^{ } dr ▽ \cdot {f}_{m} ( r ) \cdot {\int }_{{s}_{n}}^{ } {dr}^{′} g ( r , {r}^{′} ) ( {▽}^{′} ) \cdot {f}_{n} ( {r}^{′} ) \\ & \text{(9-a)} \\ {Λ}_{m , n}^{2} := {[ {jk}_{0} {\int }_{{s}_{n}}^{ } [ J ( {r}^{′} ) \frac{1}{{k}_{0}^{2}} {▽▽}_{s}^{′} \cdot J ( {r}^{′} ) ] g ( r , {r}^{′} ) ds ]}_{( r \to {r}_{m} )} \cdot & \text{(9-b)}\end{matrix}$$

where Sₘ and Sₙ are source and test triangles, rₘ is the coordinate of the corresponding observation point on the measurement plane and [symbol] is the unit tangential vector at rₘ, which for the planar case is either [symbol] or [symbol] ; Finally, m and n represent mth row and nth column in the interaction matrix, respectively. K operator can also be discretized as follows:

K_{n,m}¹:=ik∫_{S}_{ₘ}drfₘ(r)·∫_{S}_{ₙ}dr′[fₙ(r′)×∇′g(r,r′)] (10-a)

K_{n,m}²:=ik[∫_{S}_{ₙ}dr′[fₙ(r′)×∇′g(r,r′)]]_{(r→r}_{ₘ}₎· [symbol] (10-b)

In the above equation, the cross product can be extracted out of the inner integral, alternatively, which would make the integration process easier [21]. As the source and observation triangles overlap or share an edge, both inner and outer integrals become singular, and implementing equations (9) and (10) may proceed as follows [14][20] although other methods may be used without loss of generality. The singular parts of the inner integrals may be extracted and integrated using analytical methods [22][23] and the non-singular part may be solved by an adaptive quadrature method [20]. If inner and outer integrals share an edge, then the inner integral becomes singular on that edge. For the L operator, this singularity is already taken care of by extracting the gradient operator out of the inner integral [14][20]. But this singularity is still there for the K operator. Despite the singular behavior of the integrand on the whole edge, the integral can be evaluated using an adaptive numerical quadrature as the singularity is a mild logarithmic one [20][24]. In one embodiment, a triangular adaptive integral is used in which the triangles are continuously divided into three smaller ones until a specific convergence criterion is met.

Since equation (6-b) is actually a limit boundary condition, it requires attention at the discretizing step. We can move toward the center of Σ_{R}, build an inward-offset of it, and then, apply zero boundary condition to it [9]. At the end, the total system of equations can be summarized as:

$${η}_{0} [ \begin{matrix}- \frac{1}{{η}_{0}} {K}_{M , S}^{2} & - \frac{1}{{η}_{0}} {Λ}_{M , S}^{2} \\ - {Λ}_{{R}^{-} , S}^{1} & {K}_{{R}^{-} , S}^{1} \\ - {Λ}_{G , S}^{1} & {K}_{M , G}^{1}\end{matrix} \begin{matrix}- \frac{1}{{η}_{0}} {K}_{M , G}^{2} \\ - {Λ}_{{R}^{-} , G}^{1} \\ {Λ}_{M , G}^{1}\end{matrix} ] [ \begin{matrix}{C}_{js} \\ {C}_{ms} \\ {C}_{jℊ}\end{matrix} ] = [ \begin{matrix}{H}_{M} \\ 0 \\ 0\end{matrix} ] \qquad ( 11 )$$

where X_{a,b} indicates interaction submatrix between sources on surface a to an observation points on surface b. Generally, the system of equation is a rectangular one with more rows than the columns, so it is a least squares problem.

### III. Regularization

For solving the system of equations (11), direct methods like singular value decomposition (SVD) may be used, especially considering the fact that the problem is a non-square noisy matrix. Looking at equations (11), it may be possible to multiply the first equation by η₀ in order to get a better conditioning. However, by considering norms of different blocks of the matrix, the form of matrix as in (11) leads to a relatively well-conditioned matrix whose blocks have more or less similar norms. Afterwards, SVD is applied to the matrix and the truncated SVD (T-SVD) technique [25] is used to regularize the problem. For indicating the cutting threshold, the well-known L-curve is used [25]. As a check, the L-curve and Fourier coefficients are considered. These factors are calculated by applying the dot product between field space's orthogonal basis vectors (derived by SVD) and the measured fields.

### EXAMPLES

The following examples are provided to illustrate specific embodiments of the claimed invention, and not to limit the claimed invention in any manner.

### Example 1—Plane Wave Scattering

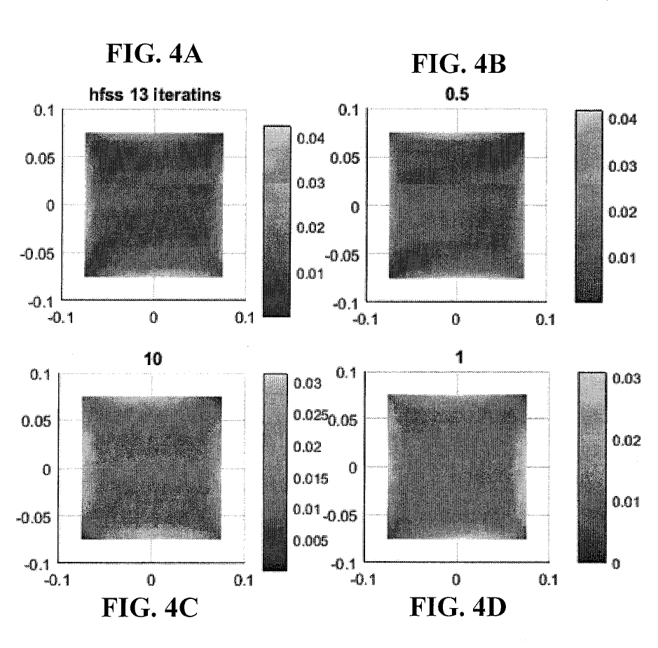

Before testing the proposed method on different scenarios, the accuracy of underlying MOM code was verified. Therefore, the MOM code is used to analyze a known scattering problem and its results are compared with those of a reliable commercial 3D full-wave simulator. Here, the scattering off a finite plane is selected because it is similar to the ground de-embedding problems. In FIGS. 4A to 4D, a PEC rectangle of size

$$( \frac{λ}{2} \times \frac{λ}{2} )$$

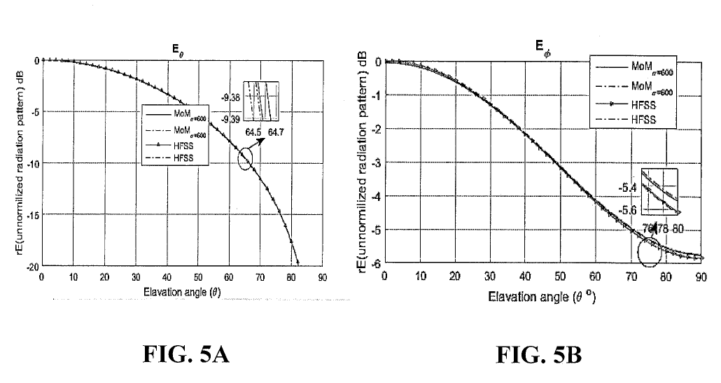

is illuminated by a plane wave with 90 degrees incident angle and both x and y polarization. The problem is solved both by commercial full-wave solver and in-house implemented code, using different mesh sizes. In the commercial solver case, once the solver is forced to go 10 and 13 iterations. The ground plane is discretized using the uniform mesh of 1 cm and 0.5 cm. As it is obvious in FIGS. 4A to 4D, in both cases as the meshing gets finer, the current density increases in amplitude and inclines toward the edges of the plane and in all the cases the back scattering results is stable. In FIGS. 5A and 5B, the back-scattering results are presented. Since the plane wave is both x and y polarized, both patterns look similar in 0 and 90 degree cuts.

### Example 2—Slot Antenna at 2 GHz

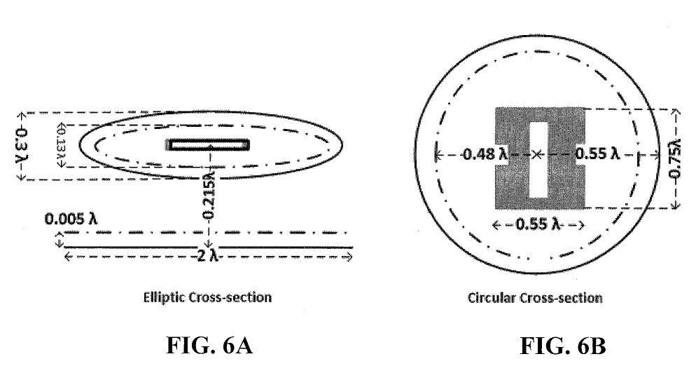

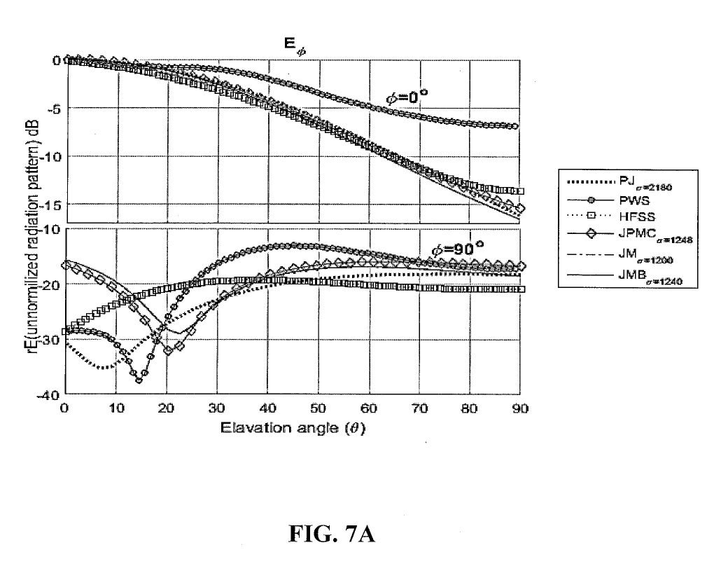

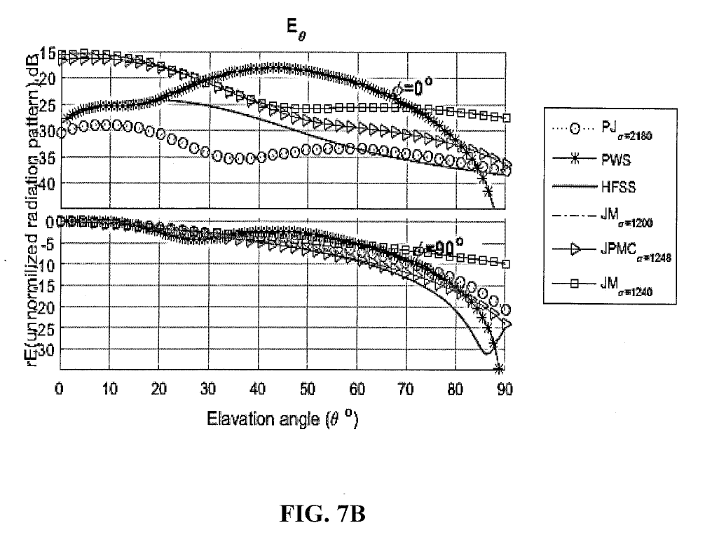

A slot antenna is selected as shown in FIG. 6A, with the sides of 0.75λ×0.55λ for the antenna and a 0.38λ×0.019λ slot on it. The aperture is excited by a transmission line on the other side with size of 0.43λ×0.024λ. The ellipsoid used for back-projection has 3 radiis of 11, 11, 3 cm with meshing element length of 1.4 cm and the dashed ellipsoid (used for Love boundary condition) has 3 radiis of 9.6, 9.6 and 2.61 cm with meshing element length of 1.22 cm. The center of ellipsoid is 4.2 cm away from the fictitious surface, which is backed by a PEC in its 1 mm distance. FIGS. 7A and 7B depict the comparison of E_{θ} and E_{ϕ} and the detailed accuracy range with 1 dB threshold can be found in Table I, for both of E_{θ} and E_{ϕ}. On average, the method including J and PMC represents more accurate results until 64 and 31 degrees compared with the conventional PWS that is 17 and 27 degrees for E_{θ} and E_{ϕ}, respectively.

TABLE I
Angular threshold of accuracy in the proposed method
compared with the HFSS results for the slot antenna

| | J and PMC | Pure J | J and M, PEC | J and M | PWS |
|---|---|---|---|---|---|
| E_{θ} | 64 | 40 | 34 | 34 | 17 |
| E_{ϕ} | 31 | 83 | 39 | 39 | 27 |

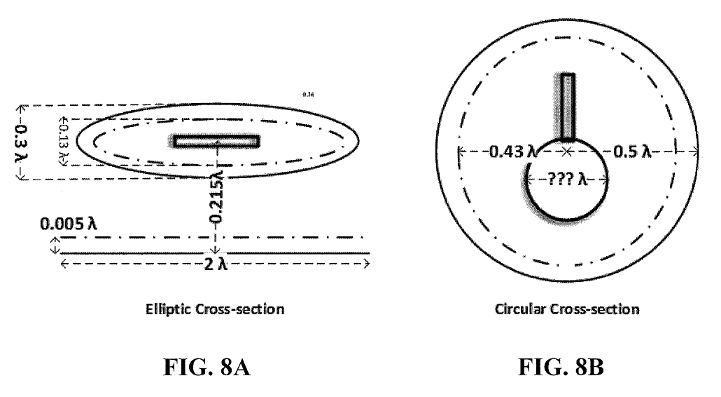

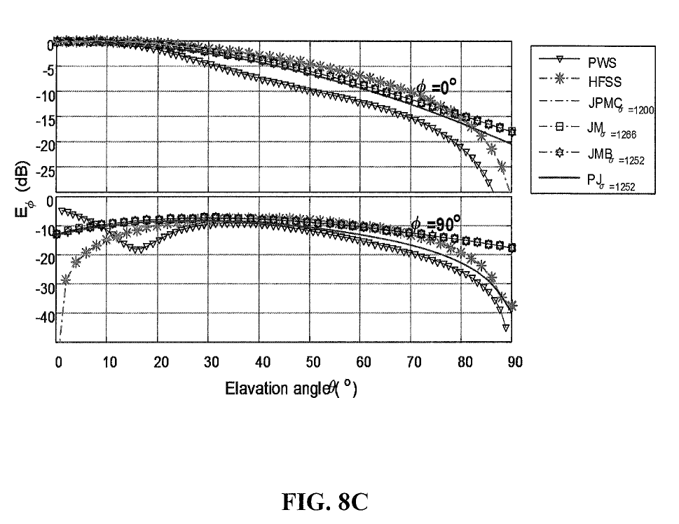

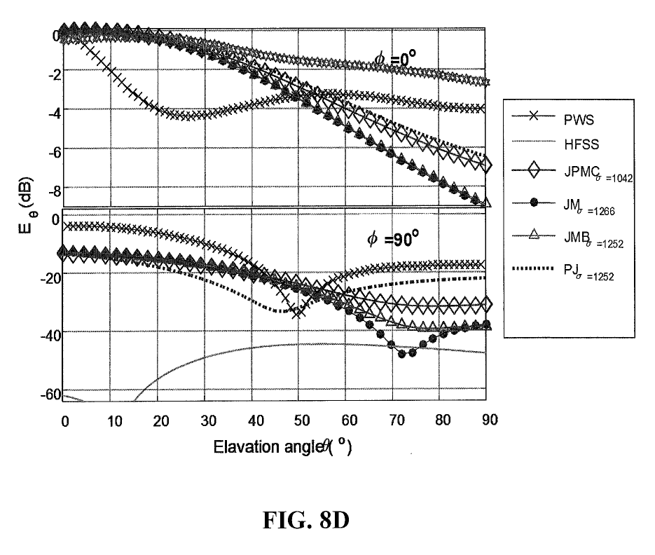

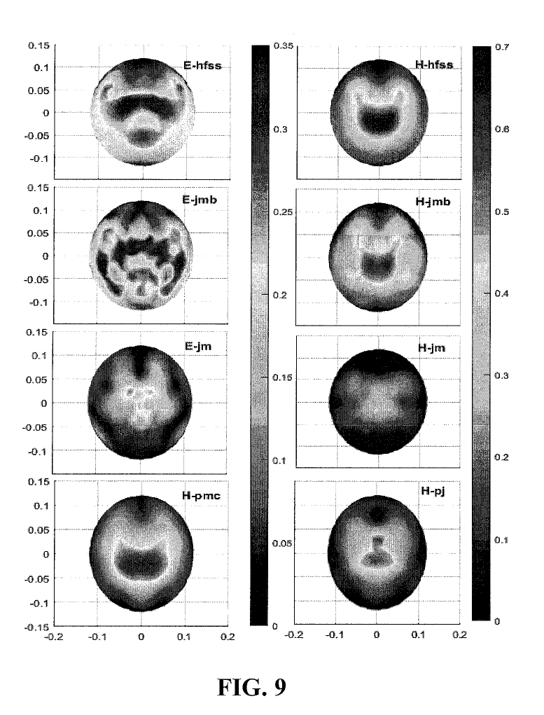

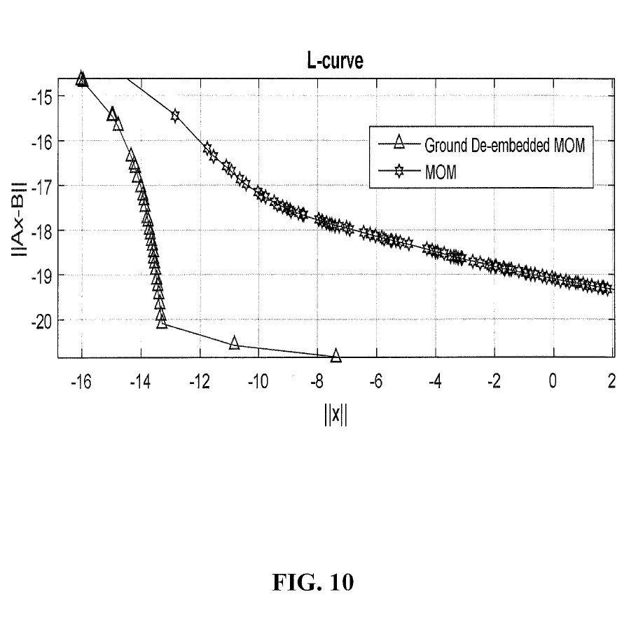

The monopole antenna shown in FIG. 8A is composed of a circular patch, 4 cm in diameter, on a substrate with no ground at its back. We chose to model the radiator using an ellipsoid of 3 radii 12, 12, and 3 cm, which completely encloses the antenna. We also choose a smaller ellipsoid with 3 radii of 9.6, 9.6, and 2.4 cm for applying Love's boundary condition. The center of the ellipsoids is 4.2 cm above the center of the fictitious surface which is backed by 1 mm distant PEC plane. FIG. 8C shows the comparison between various proposed scenarios with HFSS results over far-field distribution. The detailed information about the threshold of the accuracy in angles is given in Table II, where J and PMC boundary conditions give the most accurate results up to 40 and 54 degrees compared with the conventional that is 7 and 18 degrees of PWS method, for E_{θ} and E_{ϕ}, respectively.

TABLE II
Angular threshold of accuracy in the proposed method compared
with the HFSS results for the monopole antenna

| | J and PMC | Pure J | J and M, PEC | J and M | PWS |
|---|---|---|---|---|---|
| E_{θ} | 40 | 34 | 27 | 34 | 7 |
| E_{ϕ} | 54 | 47 | 38 | 54 | 18 |

Although the Far-Fields are more interesting, the back-projected fields can give us some idea of how accurate different proposed scenarios can be. Moreover, back projected currents can be used for diagnosis purposes and can even be used to understand the mechanisms of radiation which is important for EMC/EMI analysis. To have a quantitative comparison of back-projected fields, the monopole setup is simulated in the commercial solver and the results of the h-fields are extracted and fed into the in-house code. This way, the extract back-projected currents are known and a rigorous comparison is possible. The result of this comparison is presented in Table III. The most accurate results for both J and M currents is for the scenario with both J, M, and Love's boundary condition. For a definition of error, similar formulas as used in [9] were used.

$$\begin{matrix}{ϵ}_{J} = \frac{\vert \vert {H}_{reconstructed} - {H}_{HFSS} \vert \vert \vert}{\vert \vert {H}_{HFSS} \vert \vert} & \text{(12-a)} \\ {ϵ}_{M} = \frac{\vert \vert {E}_{reconstructed} - {E}_{HFSS} \vert \vert \vert}{\vert \vert {E}_{HFSS} \vert \vert} & \text{(12-b)}\end{matrix}$$

TABLE III
Reconstruction accuracy of the four proposed methods
compared to the HFSS and simple MOM results

| | J and PMC | Pure J | J and M, PEC | J and M |
|---|---|---|---|---|
| ϵ_{J} | 0.30 | 0.54 | 0.31 | 0.7 |
| ϵ_{M} | NA | NA | 0.45 | 0.94 |

### Definitions and Interpretation

Aspects of the present invention may be described with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The corresponding structures, materials, acts, and equivalents of all means or steps plus function elements in the claims appended to this specification are intended to include any structure, material, or act for performing the function in combination with other claimed elements as specifically claimed.

References in the specification to “one embodiment”, “an embodiment”, etc., indicate that the embodiment described may include a particular aspect, feature, structure, or characteristic, but not every embodiment necessarily includes that aspect, feature, structure, or characteristic. Moreover, such phrases may, but do not necessarily, refer to the same embodiment referred to in other portions of the specification. Further, when a particular aspect, feature, structure, or characteristic is described in connection with an embodiment, it is within the knowledge of one skilled in the art to affect or connect such module, aspect, feature, structure, or characteristic with other embodiments, whether or not explicitly described. In other words, any module, element or feature may be combined with any other element or feature in different embodiments, unless there is an obvious or inherent incompatibility, or it is specifically excluded.

It is further noted that the claims may be drafted to exclude any optional element. As such, this statement is intended to serve as antecedent basis for the use of exclusive terminology, such as “solely,” “only,” and the like, in connection with the recitation of claim elements or use of a “negative” limitation. The terms “preferably,” “preferred,” “prefer,” “optionally,” “may,” and similar terms are used to indicate that an item, condition or step being referred to is an optional (not required) feature of the invention.

The singular forms “a,” “an,” and “the” include the plural reference unless the context clearly dictates otherwise. The term “and/or” means any one of the items, any combination of the items, or all of the items with which this term is associated. The phrase “one or more” is readily understood by one of skill in the art, particularly when read in context of its usage.

### REFERENCES

The following references are incorporated herein by reference, where permitted, as if reproduced in their entirety.
[1] “EM-SCAN RFX2 Datasheet.” Emscan Corporation, 2017.
[2] D. Baudry, M. Kadi, Z. Riah, C. Arcambal, Y. Vives-Gilabert, A. Louis, et al. “Plane wave spectrum theory applied to nearfield measurements for electromagnetic compatibility investigations,” IET Sci. Meas. Technol., vol. 3 no. 1 pp. 72-83 2009.
[3] J. J. H. Wang, “An examination of the theory and practices of planar near-field measurement,” IEEE Trans. Antennas Propag., vol. 36, no. 6, pp. 746-753, June 1988.
[4] E. B. Joy and D. T. Paris, “Spatial Sampling and Filtering in Near-Field Measurements,” IEEE Trans. Antennas Propag., vol. 20, no. 3, pp. 253-261, 1972.
[5] P. Petre and T. K. Sarkar, “Differences between modal expansion and intergral equation methods for planar near-field to far-field transformation,” Prog. Electromagn. Res., vol. 12, pp. 37-56, 1996.
[6] P. Petre and T. K. Sarkar, “A planar near-field to far-field transformation using an equivalent magnetic current approach,” Antennas Propag. Soc. Int. Symp. 1992. AP-S. 1992 Dig. Held Conjunction with URSI Radio Sci. Meet. Nucl. EMP Meet. IEEE, vol. 40, no. 11, pp. 1534-1537, 1992.
[7] P. Petre and T. K. Sarkar, “Planar near-field to far-field transformation using an equivalent magnetic current approach,” IEEE Trans. Antennas Propag., vol. 40, no. 11, pp. 1348-1356, November 1992.
[8] Y. A. Lopez, F. Las-Heras Andres, M. R. Pino, and T. K. Sarkar, “An Improved Super-Resolution Source Reconstruction Method,” IEEE Trans. Instrum. Meas., vol. 58, no. 11, pp. 3855-3866, November 2009.
[9] J. L. A. Quijano and G. Vecchi, “Improved-accuracy source reconstruction on arbitrary 3-D surfaces,” IEEE Antennas Wirel. Propag. Lett., vol. 8, pp. 1046-1049, 2009.
[10] J. R. Regué, M. Ribó, J. M. Garrell, and A. Martin, “A genetic algorithm based method for source identification and far-field radiated emissions prediction from near-field measurements for PCB characterization,” IEEE Trans. Electromagn. Compat., vol. 43, no. 4, pp. 520-530, 2001.
[11] F. Las-Heras and T. K. Sarkar, “A direct optimization approach for source reconstruction and NF-FF transformation using amplitude-only data,” IEEE Trans. Antennas Propag., vol. 50, no. 4, pp. 500-510, 2002.
[12] Y. Alvarez, F. Las-Heras, and M. R. Pino, “The Sources Reconstruction Method for Amplitude-Only Field Measurements,” IEEE Trans. Antennas Propag., vol. 58, no. 8, pp. 2776-2781, August 2010.
[13] J. L. Araque Quijano and G. Vecchi, “Near- and very near-field accuracy in 3-D source reconstruction,” IEEE Antennas Wirel. Propag. Lett., vol. 9, pp. 634-637, 2010.
[14]R. Carter, “The Method of Moments in Electromagnetics, by W. C. Gibson,” Contemp. Phys., vol. 51, no. 2, pp. 183-184, 2010.
[15] P. Y. Oij ala and M. Taskinen, “Well-conditioned Muller formulation for electromagnetic scattering by dielectric objects,” IEEE Trans. Antennas Propag., vol. 53, no. 10, pp. 3316-3323, 2005.
[16] G. C. Hsiao and R. E. Kleinman, “Mathematical foundations for error estimation in numerical solutions of integral equations in electromagnetics,” IEEE Trans. Antennas Propag., vol. 45, no. 3, pp. 316-328, 1997.
[17] R. F. Harrington, Time-Harmonic Electromagnetic Fields. Wiley-IEEE Press, 2001.
[18] S. M. Rao, D. R. Wilton, and A. W. Glisson, “Electromagnetic Scattering by Surfaces of Arbitrarily Shape,” IEEE Trans. Antennas Propag., vol. 30, no. 5, pp. 409-418, 1982.
[19] and• I. K. Leven Gurel, Kubilay Sertet, “On the choice of basis functions to model surface electric current densities in computational electromagnetics,” Radio Sci., vol. 34, no. 6, pp. 1373-1387, 1999.
[20] Ö. Ergül and L. Güre, The Multilevel Fast Multipole Algorithm (MLFMA) Computational Problems. IEEE Press, 2014.
[21] R. E. Hodges and Y. Rahmat-Samii, “The evaluation of MFIE Integrals,” Microw. Opt. Technol. Lett., vol. 14, no. 1, pp. 9-14, 1997.
[22] R. D. Graglia, “On the Numerical Integration of the Linear Shape Functions Times the 3-D Green's Function or its Gradient on a Plane Triangle,” IEEE Trans. Antennas Propag., vol. 41, no. 10, pp. 1448-1455, 1993.
[23]P. Ylä-Oijala and M. Taskinen, “Calculation of CFIE impedance matrix elements with RWG and n×RWG functions,” IEEE Trans. Antennas Propag., vol. 51, no. 8, pp. 1837-1846, 2003.
[24] L. Gurel and Ergul, “Singularity of the magnetic-field integral equation and its extraction,” IEEE Antennas Wirel. Propag. Lett., vol. 4, no. 1, pp. 229-232, 2005.
[25]P. C. Hansen, “Regularization Tools A Matlab Package for Analysis and Solution of Descrete Ill-Posed Problems”, Numerical Algorithms vol. 6, no. March, pp. 1-35, 1998.

What is claimed is:

1. A ground filtering source reconstruction method for a near field measurement system comprising a scanner board with an array of integrated probes that are backed by a ground plane and at least one coupled RF receiver that captures near-field data from an antenna-under-test (AUT), the method comprising of the steps of:
(a) making near field measurements of electric and/or magnetic fields over a measurement aperture;
(b) using the near field measurement to solve for an equivalent source over a selected antenna surface as well as over a ground plane in the opposite direction;
(c) spatial filtering of reconstructed source components at the ground plane to represent the AUT in free space; and
(d) transforming the spatially filtered reconstructed source components to the far field.

2. The method of claim 1 wherein the methods to solve for an equivalent source comprises using electric and magnetic field integral equations.

3. The method of claim 2 wherein the measurement aperture and the AUT is separated by a media having non-vacuum properties comprising:
(a) electric and magnetic conductivity or loss;
(b) anisotropy; and/or
(c) inhomogeneity.

4. A near field measurement system comprising:
(a) a scanner board having an array of integrated probes backed by a ground plane and coupled to at least one RF receiver, configured to measure magnetic and/or electric fields over a measurement aperture in the near field;
(b) a module configured to solve for an equivalent source, using the near field magnetic and/or electric field measurements, over a selected antenna surface as well as over a ground plane in the opposite direction;
(c) a module to spatially filter the reconstructed source components at the ground plane to represent the AUT in free space; and
(d) a module configured to transform the spatially filtered reconstructed source components to the far field.
